(19) United States
(12) Patent Application Publication
(10) Pub. No.: US 2024/0019898 A1
(43) Pub. Date: Jan. 18, 2024

(54) MODULAR COMPUTER SYSTEM

(71) Applicant: Framework Computer LLC, Burlingame, CA (US)

(72) Inventors: Nirav Patel, San Francisco, CA (US); Poyu Chen, Taipei (TW); Travis Liu, Taipei (TW); Kasim Chang Chien, Taipei (TW); Kieran Levin, Chicago, IL (US)

(21) Appl. No.: 18/373,810

(22) Filed: Sep. 27, 2023

Related U.S. Application Data
(63) Continuation-in-part of application No. 17/949,061, filed on Sep. 20, 2022.
Application No. 17/949,061 is a continuation-in-part of application No. 17/736,765, filed on May 4, 2022.
(60) Provisional application No. 63/410,447, filed on Sep. 27, 2022.
(60) Provisional application No. 63/411,483, filed on Sep. 29, 2022.
(60) Provisional application No. 63/246,043, filed on Sep. 20, 2021.
(60) Provisional application No. 63/186,443, filed on May 10, 2021.

(51) Int. Cl. G06F 1/16; G06F 1/20; H05K 5/02; H05K 7/20

(52) U.S. Cl. CPC G06F 1/1635; G06F 1/203; H05K 5/0286; H05K 7/20136

(57) ABSTRACT

One variation of a modular computer system includes: a chassis; a graphics processing module; and a cooling module. The chassis: defines a slot; includes a controller; and a first heat pipe coupled to the controller. The cooling module includes: a first frame configured to transiently couple the chassis to locate the cooling module within the slot; and a first fan configured to couple the first heat pipe to dissipate heat transferred from the controller. The graphics processing module includes: a second frame configured to transiently couple the chassis to locate the graphics processing module within the slot; a graphics processing unit configured to electronically couple the controller; a second heat pipe coupled to the graphics processing unit; and a second fan configured to couple the first heat pipe and the second heat pipe to dissipate heat transferred from the graphics processing unit and the controller.

### CROSS-REFERENCE TO RELATED APPLICATIONS

This application claims priority to U.S. Provisional Application No. 63/410,447, filed on 27 Sep. 2022, and 63/411,483, filed on 29 Sep. 2022, each of which is incorporated in its entirety by this reference.

This application is a continuation-in-part of U.S. Non-Provisional Application Ser. No. 17/949,061, filed on 20 Sep. 2022, which claims the benefit of U.S. Provisional Application No. 63/246,043, filed on 20 Sep. 2021, each of which is incorporated in its entirety by this reference.

This application is a continuation-in-part of U.S. Non-Provisional Application Ser. No. 17/736,765, filed on 4 May 2022, which claims the benefit of U.S. Provisional Application No. 63/186,443, filed on 10 May 2021, each of which is incorporated in its entirety by this reference.

### TECHNICAL FIELD

This invention relates generally to the field of computing devices and more specifically to a new and useful method for a modular computer system in the field of computing devices.

### BRIEF DESCRIPTION OF THE FIGURES

FIG. 1 is a schematic representation of the modular computer system;

FIG. 2 is a schematic representation of the modular computer system;

FIG. 3 is a schematic representation of the modular computer system;

FIG. 4 is a schematic representation of the modular computer system;

FIG. 5 is a schematic representation of the modular computer system;

FIG. 6 is a schematic representation of the modular computer system;

FIG. 7 is a schematic representation of the modular computer system;

FIG. 8 is a schematic representation of the modular computer system;

FIG. 9 is a schematic representation of the modular computer system; and

FIG. 10 is a schematic representation of the modular computer system.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. System

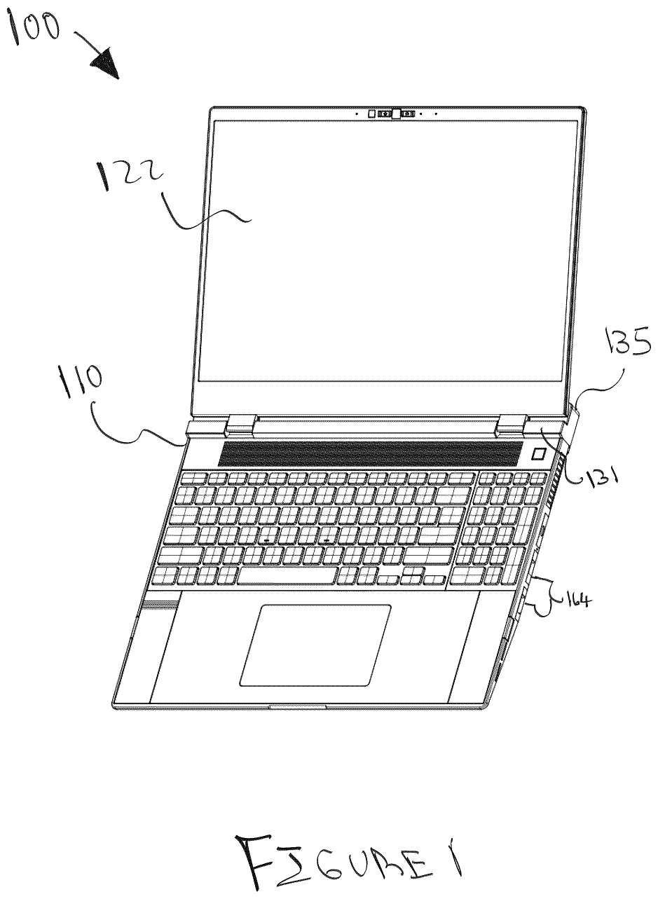

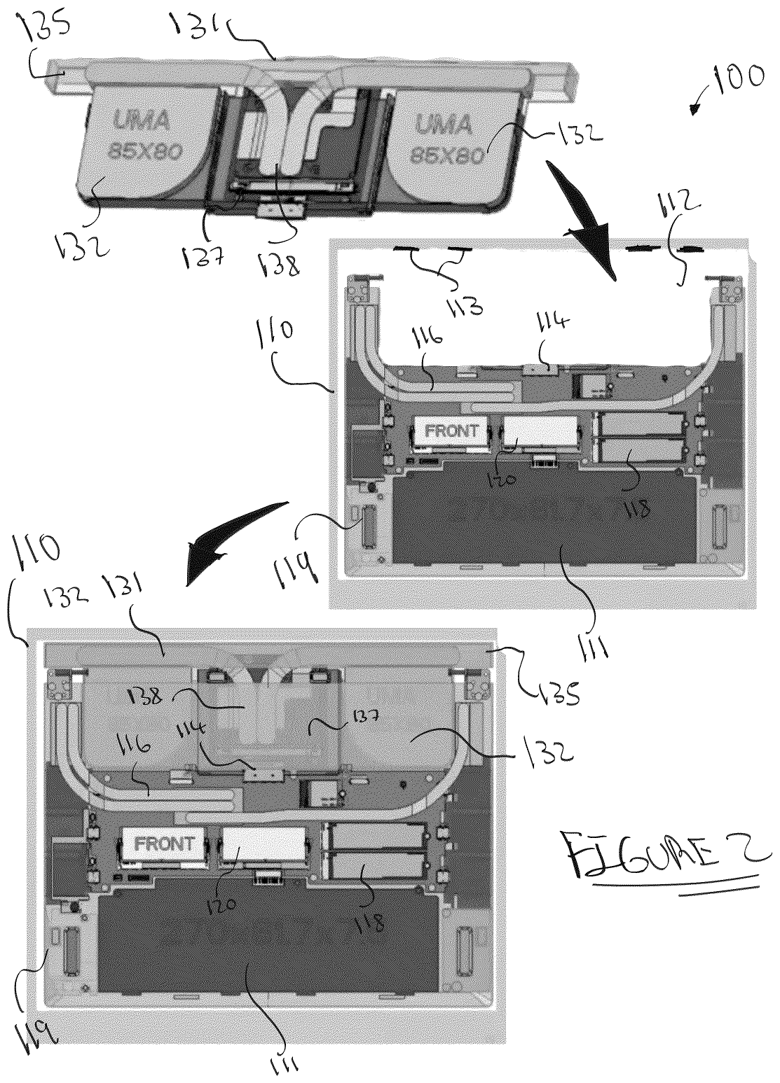

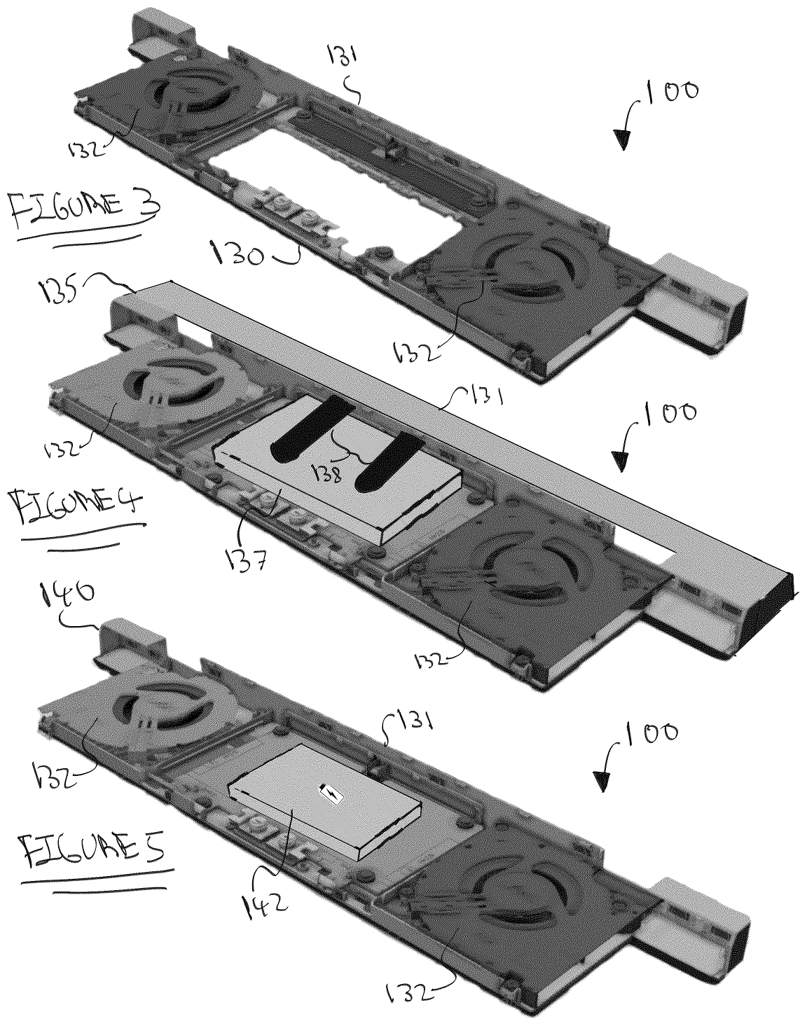

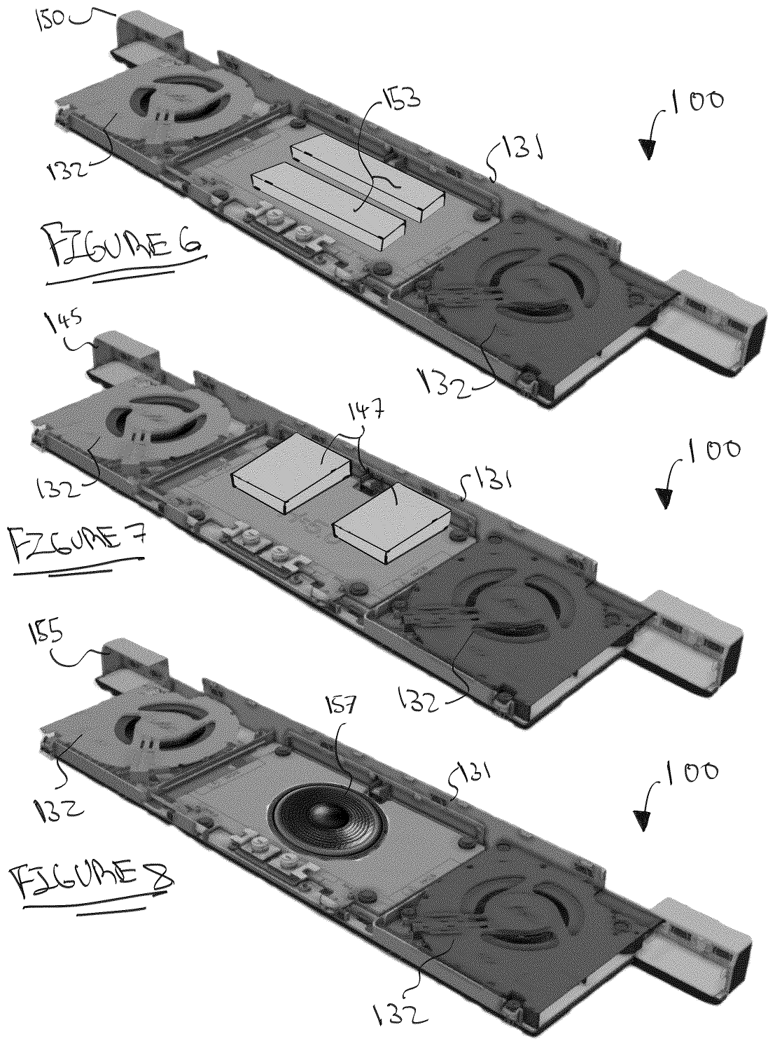

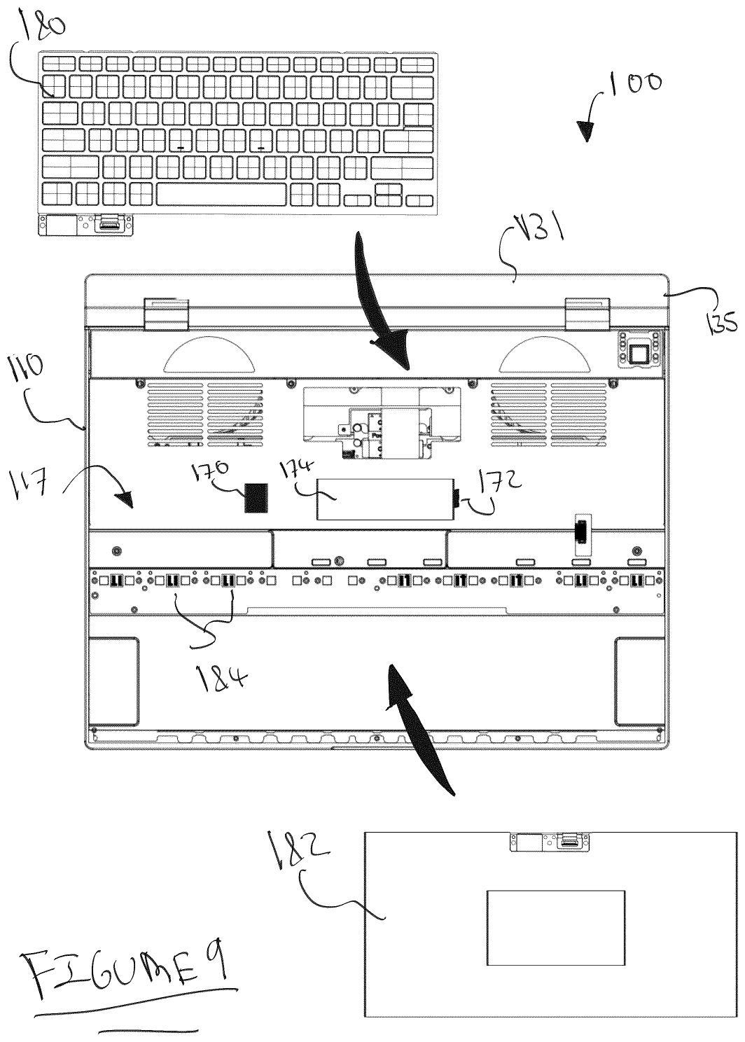

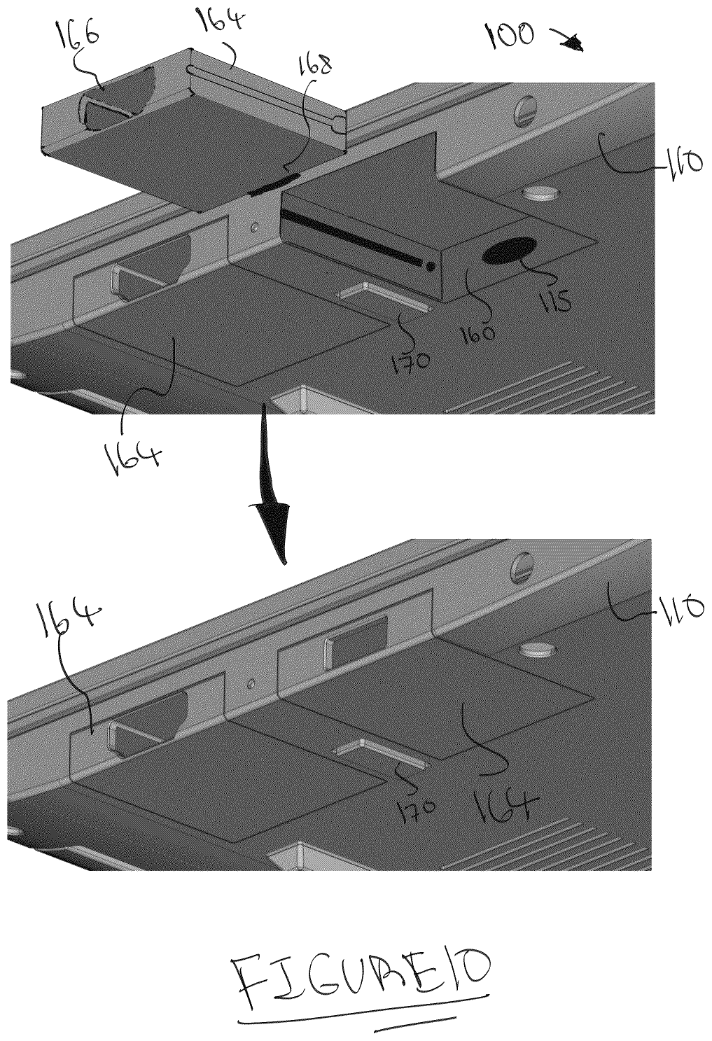

As shown in FIGS. 1, 2, and 3, a modular computer system 100 includes: a chassis 110; a display 122; and a module kit including a cooling module 130 and a graphics processing module 135.

The chassis 110: defines a module slot 112 arranged along a first lateral side of the chassis 110; and includes an electronic communication port 114 arranged within the chassis 110 and extending into the module slot 112. The chassis 110 also includes: a controller 120 arranged within the chassis 110 and electronically coupled to the electronic communication port 114; and a first set of heat pipes thermally coupled to the controller 120 and extending proximal the module slot 112 of the chassis 110. The display 122 is coupled (e.g., pivotably coupled) to the chassis 110.

The cooling module iso: defines a first mass; and includes a first frame and a first set of fans. The first frame: defines a first external geometry; and is configured to transiently couple the first lateral side of the chassis 110 to locate the cooling module 130 within the slot. The first set of fans is configured to thermally couple the first set of heat pipes to dissipate heat transferred from the controller 120.

The graphics processing module 135: defines a second mass, greater than the first mass; and includes a second frame, a graphics processing unit 137, a second set of heat pipes, and a second set of fans. The second frame: defines a second external geometry, greater than the second external geometry; and is configured to transiently couple the first lateral side of the chassis 110 to locate the graphics processing module 135 within the slot. The graphics processing unit 137 is configured to electronically couple the electronic communication port 114 to transmit electrical signals from the graphics processing unit 137 to the controller 120. The second set of heat pipes extends within the second frame and is thermally coupled to the graphics processing unit 137. The second set of fans is configured to thermally couple the first set of heat pipes and the second set of heat pipes to dissipate heat transferred from the controller 120 and the graphics processing unit 137.

The module kit is operable in a first configuration in which the cooling module 130 extends within the slot and thermally couples the controller 120 to dissipate heat generated from the controller 120.

The module kit is operable in a second configuration in which the graphics processing module 135 extends within the slot, electrically couples the controller 120 to transmit electrical signals from the graphics processing unit 137 to the controller 120, and thermally couples the controller 120 to dissipate heat generated from the controller 120 and the graphics processing unit 137.

### 2. Applications

Generally, the modular computer system 100 can operate as a standalone computing device (e.g., a 16-inch laptop computing device) including interchangeable expansion to accommodate a user's computing performance and/or interface preferences, such as battery performance, visual graphics performance, and memory performance during operation of the modular computer system 100. In particular, the modular computer system 100 includes a module kit: including a set of modules transiently mountable to a chassis 110 of the modular computer system Dm; and configured to enable a user to selectively expand operational performance, such as by expanding battery capacity of the modular computer system 100, expanding graphical processing power of the modular computer system 100, and/or expanding readable memory of the modular computer system 100, according to preferences of the user during operation of the modular computer system 100.

The modular computer system 100 includes a chassis 110: defining a module slot 112 arranged on a rear side of the chassis 110; and including an electronic communication port 114 extending within the module slot 112. Additionally, the modular computer system 100 includes a controller 120 (e.g., central processing unit): arranged within the chassis 110; and electrically coupled to the electronic communication port 114 in order to transmit electrical signals from the electronic communication port 114 to the controller 120. Accordingly, the modular computer system 100 enables a user to selectively install a first module, in the module kit, within the module slot 112 to electronically couple the electronic communication port 114, thereby enabling transferring of electrical signals from the first module to the controller 120.

Furthermore, the modular computer system 100 includes a set of controller heat pipes 116: thermally coupled to the controller 120; extending proximal the module slot 112 within the chassis 110; and configured to transfer heat generated from the controller 120 across the set of controller heat pipes 116. Accordingly, each module, in the module kit, includes a heat dissipation component (e.g., cooling fan, heat sink) configured to thermally couple the set of controller heat pipes 116 in order to dissipate heat generated by the controller 120 during operation of the modular computer system 100. Therefore, rather than integrating the heat dissipation component within the chassis 110, the modular computer system 100 includes the heat dissipation component at each module, in the module kit, thereby enabling a user to selectively replace and/or upgrade heat dissipation components—which gradually degrades during operation due to environmental exposure (e.g., dust)—for the modular computer system 100.

The module includes: a frame 131 configured to couple the rear side of the chassis 110 to transiently install the module within the module slot 112; and the heat dissipation component (e.g., cooling fan) arranged along target locations (e.g., lateral sides) of the frame 131, which couples the rear side of the chassis no in order to thermally couple the set of controller heat pipes 116 within the chassis 110 to the heat dissipation component. Therefore, rather than rigidly locating a cooling fan within the chassis no to dissipate heat from the controller 120, the modular computer system 100 includes the module kit to enable accommodation of cooling fan positions within the module slot 112, variations of cooling fan geometries in the module slot 112, and/or variations in heat dissipation components (e.g., heat sink, cooling fan, liquid cooling systems) to enable heat dissipation generated from the controller 120 and/or additional components (e.g., battery, memory unit, communication units) arranged within the chassis no and/or at the module within the module slot 112.

Therefore, the modular computer system 100 includes the module kit including a set of modules: including computer components (e.g., memory unit, battery unit, graphics processing unit 137) configured to electrically couple the controller 120 to expand operational performance of the modular computer system 100; and includes a heat dissipation component (e.g., cooling fan, heat sink) configured to thermally couple the controller 120 to dissipate heat generated form the controller 120 during operation of the modular computer system 100.

### 3. Chassis

In one implementation, the modular computer system 100 includes a chassis 110: arranged in a clamshell configuration; and including a first housing pivotably attached to a second housing in order to form a compact (i.e., foldable) modular computer system 100. In this implementation, the first housing includes: a first set of computing components; an input deck 117 arranged over the first set of computing components; the trackpad module 180 and the keyboard module 180 arranged across the input deck 117; and the set of spacer modules arranged across the input deck 117 adjacent the trackpad module 180 and the keyboard module 180. Additionally, the second housing: is congruent to the first housing; and includes a display (e.g., 16-inch display element) connected to the first housing and configured to interface with the keyboard module 180 and the trackpad module 180.

In one example, the first housing can include a first set of computing elements including a battery, a fan, a controller 120 (e.g., processor), a memory component, a storage component, a controller 120, a wireless communications component, a first speaker, a graphics processing unit 137, and speakers. In this example, each computing component in the set of computing components are selectively attachable within the chassis 110 by a uniform set of fasteners. In particular, the uniform set of fensters can transiently secure a first computing component, in the set of computing components, within the first housing of the chassis 110, and/or to a second computing component within the first housing of the chassis 110, such as to the battery, controller 120, and input deck 117.

In the aforementioned example, the second housing: is congruent the first housing; is pivotably attached to the first housing; and includes a display (e.g., 16-inch display element) arranged within the second housing and connected to the graphics processing unit 137 within the first housing. The display can transiently couple the second housing via the uniform set of fasteners, thereby enabling the display to be selectively removable from the second housing. Furthermore, the second housing can include a bezel: arranged about the display within the second housing; and magnetically coupled to the second housing.

### 4. Expansion Card

As described in U.S. Non-Provisional patent application Ser. No. 17/949,061, filed on 20 Sep. 2022, the modular computer system 100 can include a module kit containing expansion cards (e.g., memory expansion cards, port expansion cards), each transiently mounted to the first housing of the chassis 110 and configured to interface the computing components within the chassis no.

### 4.1 Card Slot

In one implementation, the system can include a card slot 160: arranged on a side end of the first housing, and configured to receive an expansion card 164, such that the expansion card 164 is flush with a lateral side face and a bottom side face of the first housing when coupled to the card slot 160. In this implementation, the card slot 160: can be located on a bottom side of the first housing, opposite the input deck 117; and defines a cavity inset from the bottom side of the first housing, thereby allowing a user to access the card slot 160 from an exterior of the modular computer system 100 without removing other components from the first housing. Furthermore, the card slot 160 can include a second electronic communication port 115: electrically connected to the controller 120 within the first housing; and interfacing with a connector (e.g., USB-type C connectors, USB-type A connectors) of the expansion card 164.

In one example, the expansion card 164 interfaces with the expansion input of the card slot 160 to form an electrical and data connection between the expansion card 164 and the controller 120 within the first housing. The controller 120 within the first housing can then: identify a type of expansion card 164 inserted within the card slot 160; and route inbound electrical signals received at the expansion input to a particular computing component within the modular computer system 100. Furthermore, the controller 120 can route outbound electrical signals, from computing components within the chassis 110, to the expansion input of the card slot 160.

Additionally, in this example the controller 120, card slot 160, and expansion card 164 utilize data transfer protocols, such as USB 2.0 and USB 3.0 data transfer protocols, to communicate data via electrical signals to computing components within the chassis 110. Furthermore, the card slot 160 at the first housing can include a mechanical latching mechanism to maintain the expansion card 164 in a connected position within the card slot 160.

### 4.2 Expansion Card

In one implementation, the modular computer system 100 includes an expansion card 164 including a card housing, a printed circuit board, a computer-side connector, and an external connector. In this implementation, the expansion card 164 can be configured to accommodate a variety of common external computer connection types. In particular, the expansion card 164 can include: a first connector 166 arranged at a first side of the card housing configured to electronically couple the second electronic communication port nib; and a second connector 168 (i.e., female external computer connector) that receives a male port connector, such as an HDMI connector, a USB type-A connector, a display port connector, or a USB type-C connector. The expansion card 164 can route electrical signals (e.g., power signals, data signals) from the computer-side connector to the external connector of the expansion card 164.

For example, the expansion card 164 can include: a computer side connector; an external power connector; and a power module 140 arranged within the card housing configured to modify a power signal input received at the external power connector and output the power signal to a battery component within the chassis 110 of the modular computer system 100 via the computer side connector.

In another example, the modular computer system 100 includes an expansion card 164 including a card housing, a storage module, and a computer-side connector. In this example, the computer-side connector of the expansion card 164 interfaces with the connector of the card slot 160 to connect the storage module of the expansion card 164 to the computing components within the chassis 110, thereby enabling the modular computer system 100 to include an external storage component.

In one implementation, the modular computer system 100 can include an expansion card 164 including: an alignment groove arranged about lateral side walls of the expansion card 164; and a latch receiver arranged at a distal end of the alignment groove and configured to couple the mechanical latching mechanism of the card slot 160. In this implementation, the alignment groove: defines a lateral channel inset from opposing side walls of the expansion card 164; and transiently couples to the rails of the card slot 160 to guide the expansion card 164 within the card slot 160, thereby preventing misalignment between the computer-side connector and the expansion input. The latch receiver interfaces with the mechanical latching mechanism to maintain the expansion card 164 within the card slot 160. Furthermore, the modular computer system 100 can include a lock release button disposed proximal the card slot 160 that, when actuated, is configured to disengage the latch receiver of the expansion card 164 from the mechanical latching mechanism of the card slot 160, thereby allowing for removal of the expansion card 164 from the card slot 160.

### 5. Input Deck

In one implementation, the modular computer system 100 includes an input deck 117: arranged across the first housing of the chassis 110; including a set of connector locations arranged across the input deck 117. Additionally, the modular computer system 100 includes a coupler: including a magnetic element and a port configured to couple the controller 120; and arranged at each connector location, in the set of connector locations, to form an array of couplers 184 across the input deck 117. In this implementation, the array of couplers 184: are arranged in a lateral configuration across a top side of the input deck 117; and configured to couple the trackpad module 180 and the keyboard module 180 to the input deck 117 arranged over the first housing of the chassis 110. Furthermore, the port at each coupler, in the array of couplers 184 is: arranged across the top side of the input deck 117; proximal a magnetic element; and configured to interface module 145 connectors located at connector tabs of the trackpad module 180 and the keyboard module 180 in order to route electrical signals (e.g., power signals, data signals) to computing components within the chassis 110.

In one example, the modular computer system 100 includes an input deck 117: defining a base of a rectangular geometry spanning a top side of the first housing; inset from the top side of the housing to define a rectangular cavity; and configured to cover the set of computing components arranged within the first housing. In this example, the input deck 117 includes the array of couplers 184: arranged in a lateral configuration across the base of the input deck 117; and spanning across a length of the base to define an upper region and a lower region for the base of the input deck 117.

In particular, a first coupler, in the array of couplers 184, can include a first magnetic element: arranged proximal a first lateral side edge of the base of the input deck 117; and arranged at a mid-point between the upper region and the lower region of the input deck 117. Furthermore, the first coupler, in the array of couplers 184, can include a second magnetic element: arranged adjacent the first magnetic element opposite the first lateral side edge of the base of the input deck 117; arranged at a midpoint-between the upper region and the lower region of the input deck 117; and defining a first spacing between the first magnetic element and the second magnetic element. Similarly, subsequent couplers, in the array of couplers 184, are arranged adjacent the first coupler to define: a linear arrangement of couplers extending from the first lateral side edge of the input deck 117 to a second lateral side edge, opposite the first lateral side edge.

In the aforementioned example, the first coupler includes the port arranged at the spacing between the first magnetic element and the second magnetic element.

Furthermore, the set of connector locations can include a first subset of connector locations and a second subset of connector locations arranged across the input deck 117. In particular, the first subset of connector locations: is arranged proximal the first lateral side edge of the input deck 117; and defines a first linear arrangement of connector locations between the upper region and the lower region of the input deck 117. Furthermore, the second subset of connector locations: is arranged proximal a second lateral side edge of the input deck 117, opposite the first lateral side edge; and defines a second linear arrangement of ports between the upper region and the lower region of the input deck 117.

In one implementation, the modular computer system 100 can execute a scan cycle in order to: read electrical values from the port at each coupler, in the array of couplers 184; and detect presence of input modules and/or spacer modules arranged across the input deck 117 based on these electrical values. For example, the system can: read voltage values from the port; and detect presence of a resistor divider at the input modules based on voltage values retrieved from each port. The system can then: interpret an operational mode for the input deck 117 in response to detecting presence of a module coupled to each port in the array of couplers 184 across the input deck 117; and/or interpret a modification mode for the input deck 117 in response to detecting absence of a module from a port in the array of couplers 184. In the modification mode, the modular computer system 100 can terminate routing of power signals to the input modules thereby allowing for a user to safely reconfigure modules across the input deck 117 while minimizing risk of electrical failure during removing and mounting of modules across the input deck 117.

Therefore, the modular computer system 100 can include an array of couplers 184: defining an upper region and a lower region of the input deck 117; and including a port and a magnetic element configured to interface with a connector tab of the trackpad module 180 and the keyboard module 180. As a result, the input deck 117: can selectively receive a set of input modules, such as the trackpad module 180 and the keyboard module 180, in various positions across the upper region and the lower region of the input deck 117 via magnetic coupling to the magnetic element; and can interface the set of input modules via the port to route electrical signals (e.g., power signals, data signals) between the set of input modules and computing components within the chassis 110.

### 6. Input Modules

Generally, the modular computer system 100 includes a set of input modules including: a keyboard module 180 arranged across the upper region of the input deck 117; and a trackpad module 180 arranged across the lower region of the input deck 117. Each input module, in the set of input modules, includes a connector tab transiently couplable to the array of couplers 184 across the input deck 117 in order to selectively position the input module in a preferred configuration (e.g., right-sided configuration, left-sided configuration, center configuration) according to a user's preferences during operation of the modular computer system 100.

### 6.1 Connector Tab

In one implementation, the modular computer system 100 includes each of the input modules and the keyboard module 180 including a connector tab. The connector tab: is configured to magnetically couple at a first coupler, in the set array of couplers 184, across the input deck 117; and includes a module connector configured to interface with a port at the first coupler in the array of couplers 184. In this implementation, the module connector is configured to transfer electrical signals (e.g., data signals) from the trackpad module 180 and/or the keyboard module 180 to the set of computing components within the first housing of the chassis 110. The modular computer system 100 can then implement one or more data transfer protocols, such as USB, USB 2.0 and USB 3.0, to communicably couple the keyboard module 180 to the set of computing components within the chassis 110.

In one example, the connector tab: is formed of a ferrous material configured to magnetically couple a magnetic element arranged at a first coupler, in the array of couplers 184, across the input deck 117; is arranged on a bottom side of the trackpad module 180 and/or keyboard module 180; and includes a module connector (e.g., female pogo pin connecter) centrally arranged at the connector tab and configured to communicably couple the port at the first coupler, in the array of couplers 184, arranged across the input deck 117.

### 6.2 Keyboard Module

In one implementation, the modular computer system 100 includes a keyboard module 180: including a set of alphanumeric keys arranged across a top side of the keyboard module 180; including a first connector tab arranged on a bottom side of the keyboard module 180 configured couple at a first coupler, in the array of couplers 184, of the input deck 117; and arranged across the upper region of the input deck 117 in a first keyboard module 180 position. In this implementation, the keyboard module 180 can be arranged in one of a center configuration, a left-sided configuration, or a right-sided configuration across the upper region of the input deck 117.

In one example, the keyboard module 180: is arranged across the upper region of the input deck 117 proximal a left-lateral side of the first housing; defines a first area across the upper region of the input deck 117; and defines a second area, less than the first area, across the upper region of the input deck 117. In this example, the keyboard module 180: includes a first connector tab coupled at a coupler proximal the left-lateral side of the first housing; and spans across the first area of the upper region of the input deck 117 to form the left-sided configuration for the keyboard module 180. Similarly, the keyboard module 180: can be arranged across the upper region of the input deck 117 proximal a right-lateral side of the first housing; includes the first connector tab coupled at a coupler proximal the right-lateral side of the first housing; and spans across a first area of the upper region of the input deck 117 to form the right-sided configuration for the keyboard module 180.

In another example, the keyboard module 18o: is centrally arranged across the upper region of the input deck 117; defines a first area across the upper region of the input deck 117; defines a second area, less than the first area, adjacent the keyboard module 180 and proximal the left-lateral side of the first housing; and defines a third area, less than the first area, adjacent the keyboard module 180 and proximal a right-lateral side of the first housing of the chassis 110. In this example, the keyboard module 180: includes a first connector tab coupled at a coupler arranged proximal a center of the input deck 117; and spans the first area across the center of the upper region of the input deck 117 to form the center configuration for the keyboard module 180.

Therefore, the modular computer system 100: can include a keyboard module 180 transiently mountable to the input deck 117; can include the keyboard module 180 selectively positioned across multiple areas across the upper region of the input deck 117 according to preferences of a user operating the modular computer system 100; and is configured to detect keyboard inputs based on electrical signals output by the keyboard module 180 regardless of the keyboard module 180 position across the input deck 117.

### 6.3 Trackpad Module

In one implementation, the modular computer system 100 includes a trackpad module 180: including a touch sensor arranged on a top side of the trackpad module 180; including a second connector tab arranged on a bottom side of the trackpad module 180 configured to couple a second coupler, in the array of couplers 184, different from the first coupler, on the input deck 117; and arranged across the lower region of the input deck 117 in a first trackpad module 180 position. In this implementation, the trackpad module 180 can cooperate with the keyboard module 180 to be arranged in one of a center configuration, a left-sided configuration, or a right-sided configuration across the lower region of the input deck 117.

In one example, the trackpad module 180: is arranged across the lower region of the input deck 117 proximal the left-lateral side of the first housing; adjacent the keyboard module 180 arranged across the upper region of the input deck 117; defines a first area across the lower region of the input deck 117; and defines a second area, less than the first area, across the lower region of the input deck 117. In this example, the trackpad module 180: includes a second connector tab coupled at a second coupler, proximal the first coupler coupled to the first connector tab of the keyboard module 18o, and proximal the left-lateral side of the first housing; and spans across the first area of the lower region of the input deck 117 to form the left-sided configuration for the trackpad module 180.

Similarly, the trackpad module 180 can: be arranged across the lower region of the input deck 117 proximal the right-lateral side of the first housing; be adjacent the keyboard module 180 arranged across the upper region of the input deck 117; include the second connector tab coupled at a second coupler proximal the right-lateral side of the first housing; and span across a first area of the lower region of the input deck 117 to form the right-sided configuration for the trackpad module 180.

In another example, the trackpad module 180: is centrally arranged across the lower region of the input deck 117; is arranged proximal the trackpad module 180 across the upper region of the input deck 117; defines a first area across the lower region of the input deck 117; defines a second area, less than the first area, adjacent the trackpad module 180 and proximal the left-lateral side of the first housing; and defines a third area, less than the first area, adjacent the trackpad module 180 and proximal a right-lateral side of the first housing of the chassis 110. In this example, the trackpad module 180: includes the second connector tab coupled at a second coupler proximal a center of the input deck 117; and spans the first area across the center of the lower region of the input deck 117 to form the center configuration for the trackpad module 180.

Therefore, the modular computer system 100: can include a trackpad module 180 transiently mountable to the input deck 117; can include the trackpad module 180 selectively positioned across multiple areas across the lower region of the input deck 117 according to preferences of the user operating the modular computer system 100; and is configured to detect touch inputs based on electrical signals output by the trackpad module 180 regardless of the trackpad module 180 position across the input deck 117.

### 7. Module Slot

Generally, the modular computer system 100 includes a module slot 112: arranged along a lateral side of the chassis 110; and configured to couple a particular module, in the module kit, within the module slot 112 in order to interface with components (e.g., controller 120S, batteries, memory) arranged within the chassis 110. More specifically, each module, in the module kit, is configured to: mechanically couple the chassis 110 to transiently install the particular module within the module slot 112; thermally couple the controller 120 to dissipate heat generated from the controller 120; and electrically couple the controller 120 to transfer electric signals from the particular module to the controller 120.

In one implementation, the modular computer system 100 can include the module slot 112: arranged at a rear side of the chassis 110 opposite the display coupled to the chassis 110; and defining a rectangular geometry within the chassis 110 cooperating with a geometry of each module in the module kit. In this implementation, the modular computer system 100 includes: an electronic communication port 114 (e.g., 15-pin connector, 19-pin connector) arranged within the chassis 110 and extending into the module slot 112; and a controller 120 (e.g., a central processing unit) electrically coupled to the electronic communication port 114 and configured to transmit electrical signals, received at the electronic communication port 114, to the controller 120.

Accordingly, the modular computer system 100 can: transiently install a particular module, in the module kit, within the module slot 112; and electronically couple the electronic communication port 114 to transfer electrical signals from module components (e.g., battery, memory) arranged at the particular module to the controller 120 within the chassis 110.

In one example, the chassis 110 includes a set of magnetic elements 113: arranged along the rear side of the chassis 110; and configured to magnetically couple a particular module, in the module kit, to transiently install the particular module within the module slot 112. In particular, a module, in the module kit: magnetically couples the set of magnetic elements 113 along the rear side of the chassis 110 to transiently retain the particular module coupled to the chassis no; and electronically couples the electronic communication port 114 to transfer electrical signals from the particular module to the controller 120. Therefore, the modular computer system 100 can magnetically and electronically couple modules in the module kit in order to selectively expand operational performance (e.g., battery performance, memory performance) of the modular computer system 100.

Additionally, the modular computer system 100 includes a set of controller heat pipes 116: thermally coupled to the controller 120 within the chassis no; extending proximal the module slot 112 of the chassis no; and configured to thermally couple a heat dissipation component (e.g., cooling fan, heat sink, liquid cooling) to dissipate heat generated from the controller 120 during operation of the modular computer system 100. Accordingly, a particular module, in the module kit, can include a heat dissipation component (e.g., cooling fan, heat sink): thermally coupling the set of controller heat pipes 116 extending within the chassis no; and configured to dissipate heat transferred from the controller 120 during operation of the modular computer system 100.

Therefore, the modular computer system 100 can also magnetically, electronically, and thermally couple modules in the module kit in order to selectively expand operational performance (e.g., battery performance, memory performance, computational performance) of the modular computer system 100 according to preferences of a user interfacing with the modular computer system 100.

### 8. Module Kit

Generally, modules contained in the module kit include computer components (e.g., memory, processors, batteries) configured to interface with computer components (e.g., memory, processors, batteries) arranged within the chassis 110, thus enabling operators to selectively install a particular module, in the module kit, to selectively expand operational performance (e.g., battery performance, memory performance) of the modular computer system 100. More specifically, the modular computer system 100 enables a user to selectively expand operational performance of the modular computer system 100, such as by expanding battery capacity of the modular computer system 100, expanding graphical processing power of the modular computer system 100, and/or expanding readable memory of the modular computer system 100, according to preferences of the user during operation of the modular computer system 100.

During operation, the modular computer system 100 includes a module, in the module kit, installed within the module slot 112 in order to maintain the modular computer system 100 in an operational mode. In particular, while in the operational mode, the controller 120 generates heat, which is then transferred along the set of controller heat pipes 116 in order to be dissipated by a heat dissipation component (e.g., heat sink, cooling fan) separate from the computer components arranged within the chassis no. Accordingly, each module, contained in the module kit, includes a heat dissipation component (e.g., heat sink, cooling fan) configured to thermally couple the set of controller heat pipes 116 when installed into the module slot 112 of the chassis no.

### 8.1 Cooling Module

In one implementation, the module kit includes a cooling module 130 comprising: a frame 131 defining a rectangular geometry and configured to transiently couple the lateral side of the chassis no to locate the cooling module 130 within the module slot 112; and a set of fans 132 (e.g., cooling fans) coupled to the frame 131 and configured to thermally couple the first set of controller heat pipes 116 to dissipate heat transferred from the controller 120. Thus, the modular computer system 100 enables a user to selectively install the cooling module 130 within the module slot 112 in order to thermally couple the controller 120 (e.g., processor) within the chassis no to the cooling module 130 and thus dissipate heat generated by the controller 120 during operation of the modular computer system 100.

In one example, the cooling module 130 includes: a frame 131 formed of a ferrous material and configured to magnetically couple the rear side of the chassis 110 to transiently install the cooling module 130 within the module slot 112; a first fan arranged proximal a first lateral edge of the frame 131 and configured to thermally couple a first controller heat pipe, in the set of controller heat pipes 116, proximal the module slot 112; and a second fan arranged proximal a second lateral edge, opposite the first lateral edge, of the frame 131 and configured to thermally couple a second controller heat pipe, in the set of controller heat pipes 116, proximal the module slot 112. Therefore, the modular computer system 100 is operable in a cooling module configuration in which the cooling module 130 extends within the module slot 112, and in which the cooling module 130 is thermally coupled to the controller 120 in order to dissipate heat generated at the controller 120 by transferring heat generated at the controller 120 to the first fan and the second fan via the set of connector heat pipes.

In one implementation, the cooling module configuration for the modular computer system 100 corresponds to a default module configuration necessary to initiate the modular computer system 100 into an operational mode in which the modular computer system 100 can activate software applications executing on the controller 120, activate content rendered on the display, and activate a power connection to the electronic communication port 114. For example, during a startup cycle, the modular computer system 100 can: read a first set of electrical signals from the electronic communication port 114 within the chassis 110; and detect absence of a module installed within the module slot 112 based on the first set of electrical signals. Accordingly, the modular computer system 100 can: generate a prompt requesting the user to install the cooling module 130 at the module slot 112 of the chassis 110; display (e.g., render) this prompt on the display coupled to the chassis 110; and, maintain the modular computer system 100 in the startup cycle in which the controller 120 disables a power connection to the electronic communication port 114 to enable the user to install the cooling module 130. The modular computer system 100 can then: read a second set of electrical values from the electronic communication port 114 within the chassis 110; detect installation of the cooling module 130 within the module slot 112 based on the first set of electrical values; and, in response to detecting installation of the cooling module 130, terminate the startup cycle for the modular computer system 100 and initiate the modular computer system 100 into the operational mode.

Therefore, the modular computer system 100 can include the cooling module 130, transiently installed within the module slot 112, in order to enable the dissipation of heat generated from the controller 120 within the chassis 110 during operation of the modular computer system 100.

### 8.2 Graphics Processing Module

In one implementation, the module kit includes a graphics processing module 135 including: a frame 131 defining a rectangular geometry and configured to transiently couple the lateral side of the chassis 110 to locate the graphics processing module 135 within the module slot 112; and a graphics processing unit 137 coupled to the frame 131 and configured to electronically couple the electronic communication port 114 to transmit electrical signals from the graphics processing unit 137 to the controller 120. Additionally, the graphics processing module 135 includes: a set of graphics processing unit heat pipes 138 extending within the frame 131 and thermally coupled to the graphics processing unit 137; and a set of fans 132 configured to thermally couple the set of controller heat pipes 116 and the set of graphics processing unit heat pipes 138 to dissipate heat transferred from the controller 120 and the graphics processing unit 137.

Thus, the modular computer system 100 enables a user to selectively install the graphics processing module 135 within the module slot 112 in order to thermally couple the controller 120 and the graphics processing unit 137 to the set of fans 132 on the graphics processing module 135. Accordingly, the modular computer system 100 can dissipate heat generated by the controller 120 and the graphics processing unit 137 during operation of the modular computer system 100.

In one example, the graphics processing module 135 includes: a frame 131 formed of a ferrous material and configured to magnetically couple the rear side of the chassis 110 to transiently install the graphics processing module 135 within the module slot 112; a first fan arranged proximal a first lateral edge of the frame 131 and configured to thermally couple a first controller 120 heat pipe, in the set of controller heat pipes 116, proximal the module slot 112; and a second fan arranged proximal a second lateral edge, opposite the first lateral edge, of the frame 131 and configured to thermally couple a second controller 120 heat pipe, in the set of controller heat pipes 116, proximal the module slot 112. In this example, the graphics processing module 135 includes: the graphics processing unit 137 coupled to the frame 131 and interposed between the first fan and the second fan; and the set of graphics processing unit heat pipes 138 extending within the frame 131 to couple the first fan and the second fan.

Therefore, the modular computer system 100 is operable in a graphics processing module 135 configuration in which: the graphics processing module 135 extends within the module slot 112; the graphics processing module 135 is thermally coupled to the controller 120 in order to dissipate heat generated by the controller 120; the graphics processing module 135 is thermally coupled to the graphics processing unit 137 in order to dissipate heat generated by the graphics processing unit 137; and the graphics processing module 135 is electrically coupled to the controller 120 to transmit electrical signals from the graphics processing unit 137.

In one implementation, the graphics processing module 135: defines a first mass greater than a second mass of the cooling module 13o; and defines a first external geometry greater than a second external geometry of the cooling module 130 when installed within the module slot 112 of the chassis 110. For example, the graphics processing module 135 configuration includes the graphics processing module 135 extending within the module slot 112 to locate the frame 131 extending outwardly from the rear side of the chassis 110. Alternatively, the cooling module configuration includes the cooling module 130 extending within the module slot 112 to locate the frame 131 flush with the rear side of the chassis 110.

Therefore, the modular computer system 100 can include the graphics processing module 135 transiently installed within the module slot 112 in order to: enable dissipation of heat generated from the controller 120 within the chassis 110; and expand graphical processing performance during operation of the modular computer system 100.

### 8.3 Power Module

In one implementation, the modular computer system 100 includes a first battery 111: arranged within the chassis 110; defining a first energy storage capacity; and configured to electrically couple the controller 120 to transmit electrical energy stored within the first battery 111 to computer components arranged within the chassis 110. In this implementation, the modular computer system 100 includes a power module 140 configured to install within the chassis 110 in order to expand electrical energy storage capacity during operation of the modular computer system 100.

The module kit includes a power module 140 including: a frame 131 defining a rectangular geometry and configured to transiently couple the lateral side of the chassis 110 to locate the power module 140 within the module slot 112; and a second battery 142 defining a second energy storage capacity, greater than the first energy storage capacity, and configured to electrically couple the electronic communication port 114 to transmit electrical energy stored within the second battery 142 to the controller 120 within the chassis 110. Additionally, the power module 140 includes: a set of battery heat pipes extending within the frame 131 and thermally couple to the second battery 142; and a set of fans 132 configured to thermally couple the set of controller heat pipes 116 and the set of battery heat pipes to dissipate heat transferred from the controller 120 and the second battery 142.

Thus, the modular computer system 100 enables a user to selectively install the power module 140 within the module slot 112 in order to thermally couple the controller 120 and the second battery 142 to the set of fans 132 on the power module 140. Accordingly, the modular computer system 100 can dissipate heat generated by the controller 120 and the second battery 142 during operation of the modular computer system 100.

In one example, the power module 140 includes: a frame 131 formed of a ferrous material and configured to magnetically couple the rear side of the chassis 110 to transiently install the power module 140 within the module slot 112; a first fan arranged proximal a first lateral edge of frame 131 and configured to thermally couple a first controller heat pipe, in the set of controller heat pipes 116, proximal the module slot 112; and a second fan arranged proximal a second lateral edge, opposite the first lateral edge, of the frame 131 and configured to thermally couple a second controller 120 heat pipe, in the set of controller heat pipes 116, proximal the module slot 112. In this example, the power module 140 includes: the second battery 142 coupled to the frame 131 and interposed between the first fan and the second fan; and the set of battery heat pipes extending within the frame 131 to couple the first fan and the second fan.

Therefore, the modular computer system 100 is operable in a power module 140 configuration in which: the power module 140 extends within the module slot 112; the power module 140 is thermally coupled to the controller 120 in order to dissipate heat generated by the controller 120; the power module 140 is thermally coupled to the second battery 142 in order to dissipate heat generated by the second battery 142; and the power module 140 is electrically coupled to the controller 120 to transmit electrical energy stored within the second battery 142 to computer components (e.g., ports, memory, battery) within the chassis 110.

In one implementation, the modular computer system 100 can prioritize conserving electrical charge stored within the first battery in by directing electrical energy—stored within the second battery 142—to computer components within the chassis 110 while maintaining a battery saver mode for the first battery in. Accordingly, upon draining electrical energy stored in the second battery 142, the modular computer system 100 can then deactivate the battery saver mode for the first battery 111 to direct electrical energy—stored within the first battery 111—to computer components within the chassis no. For example, during a first time period, the modular computer system 100 can: at a first time, read a first state of charge from the first battery in arranged within the chassis no; and, in response to the first state of charge exceeding a threshold state of charge, direct electrical energy stored within the second battery 142 to the controller 120. The modular computer system 100 can then: at a second time following the first time, read a second state of charge from the second battery 142 of the power module 140; and, in response to the second state of charge falling below a threshold state of charge, direct electrical energy stored within the first battery 111 to the controller 120.

In another implementation, during a recharging period, the modular computer system 100 can prioritize charging of the first battery in within the chassis no prior to charging the second battery 142 on the power module 140. Accordingly, the modular computer system 100 can: detect a state of charge for the first battery 111 falling below a threshold state of charge; and, in response to the state of charge falling below the threshold state of charge, supply electrical energy stored in the second battery 142 toward the first battery 111 to increase the state of charge of the first battery 111. For example, during a second time period, the modular computer system 100 can: at a third time, read a third state of charge from the first battery in arranged within the chassis no; and detect the third state of charge falling below a threshold state of charge. Additionally, in response to the third state of charge falling below the threshold state of charge, the modular computer system 100 can: direct electrical energy stored within the second battery 142 to the controller 120; and direct electrical energy stored within the second battery 142 to the first battery 111 to increase electrical energy stored within the first battery in.

Therefore, the modular computer system 100 can include the power module 140 transiently installed within the module slot 112 in order to: enable dissipation of heat generated from the controller 120 within the chassis no; and expand energy storage capacity during operation of the modular computer system 100.

### 8.4 Interface Module

In one implementation, the modular computer system 100 includes an interface module 145 including: a frame 131 defining a rectangular geometry and configured to magnetically couple the rear side of the chassis no to transiently install the interface module 145 within the module slot 112; a set of connectors 147 (e.g., display ports, data ports, memory slots) arranged along the frame 131 and configured to electronically couple the electronic communication port 114 to transmit electrical signals from peripheral devices coupled to the set of connectors 147; and a set of fans 132 configured to thermally couple the set of controller heat pipes 116 to dissipate heat transferred from the controller 120. Thus, the modular computer system 100 enables a user to selectively install the interface module 145 within the module slot 112 in order to thermally couple the controller 120 to the set of fans 132 on the interface module 145. The modular computer system 10o can then dissipate heat generated from the controller 120 during operation of the modular computer system 100.

Accordingly, the modular computer system 100 is operable in an interface module 145 configuration in which: the interface module 145 extends within the module slot 112; the interface module 145 is thermally coupled to the controller 120 in order to dissipate heat generated by the controller 120; and the interface module 145 is electrically coupled to the controller 120 to transmit electrical signals from the set of connectors 147. Therefore, the modular computer system 100 can include the interface module 145 transiently installed within the module slot 112 in order to: enable dissipation of heat generated from the controller 120 within the chassis 110; and expand a quantity of connectors (e.g., display ports, card slots) during operation of the modular computer system 100.

### 8.5 Memory Module

In one implementation, the modular computer system 100 includes a first memory unit 118: arranged within the chassis 110; defining a first memory storage capacity; and configured to electrically couple the controller 120 to transmit data stored within the first memory unit 118 to the controller 120. In this implementation, the modular computer system 100 includes a memory module 150 configured to install within the chassis 110 in order to expand memory storage capacity during operation of the modular computer system Dm.

The module kit includes the memory module 150 including: a frame 131 defining a rectangular geometry and configured to magnetically couple the rear side of the chassis 110 to transiently install the memory module 150 within the module slot 112; a second memory unit 153 defining a second memory storage capacity, greater than the first energy storage capacity, and configured to electrically couple the electronic communication port 114 to transmit data stored within the second memory unit 153 to the controller 120; and a set of fans 132 configured to thermally couple the set of controller heat pipes 116 to dissipate heat transferred from the controller 120. Thus, the modular computer system 100 enables a user to selectively install the memory module 150 within the module slot 112 in order to thermally couple the controller 120 to the set of fans 132 on the memory module 150. The modular computer system 100 can then dissipate heat generated from the controller 120 during operation of the modular computer system 100.

Accordingly, the modular computer system 100 is operable in a memory module configuration in which the memory module 150 extends within the module slot 112, in which the memory module 150 is thermally coupled to the controller 120 in order to dissipate heat generated by the controller 120, and in which the memory module 150 is electrically coupled to the controller 120 to transmit data stored within the second memory unit 153 to the controller 120. Therefore, the modular computer system 100 can include the memory module 150 transiently installed within the module slot 112 in order to: enable dissipation of heat generated from the controller 120 within the chassis 110; and expand a memory storage capacity during operation of the modular computer system 100.

### 8.6 Audio Module

In one implementation, the modular computer system 100 includes a first speaker unit 119: arranged within the chassis 110; defining a first frequency threshold (e.g., 20,000 Hertz); and configured to electrically couple the controller 120 to broadcast audio signals from the first speaker unit 119. In this implementation, the modular computer system 100 includes an audio module 155 configured to install within the chassis 110 in order to expand audio broadcast bandwidth during operation of the modular computer system 100.

The module kit includes the audio module 155 including: a frame 131 defining a rectangular geometry and configured to magnetically couple the rear side of the chassis 110 to transiently install the audio module 155 within the module slot 112; a second speaker unit 157 (e.g., subwoofer) defining a second frequency threshold (e.g., 200 Hertz), less than the first frequency threshold, and configured to electrically couple the electronic communication port 114 to broadcast audio signals from the second speaker unit 157; and a set of fans 132 configured to thermally couple the set of controller heat pipes 116 to dissipate heat transferred from the controller 120. Thus, the modular computer system 100 enables a user to selectively install the audio module 155 within the module slot 112 in order to thermally couple the controller 120 to the set of fans 132 on the audio module 155. The modular computer system 100 can then dissipate heat generated from the controller 120 during operation of the modular computer system 100.

Accordingly, the modular computer system 100 is operable in an audio module configuration in which: the audio module 155 extends within the module slot 112; the audio module 155 is thermally coupled to the controller 120 in order to dissipate heat generated by the controller 120; and the audio module 155 is electrically coupled to the controller 120 to broadcast audio signals from the first speaker unit 119 and the second speaker unit 157. Therefore, the modular computer system 100 can include the audio module 155 transiently installed within the module slot 112 in order to: enable dissipation of heat generated from the controller 120 within the chassis 110; and expand audio broadcast bandwidth during operation of the modular computer system 100.

### 9. Module Swap

Generally, the modular computer system 100 can initiate a low power mode in which the controller 120 disables power supplied to the electronic communication port 114 in order to enable a user to exchange a module installed within the module slot 112 with a different module in the module kit. More specifically, the modular computer system 100 can: generate a prompt requesting a user to select a particular module in the module kit for installation in the module slot 112 of the chassis 110; display the prompt at the display for the user; and, in response to receive a selection from the user, initiate the lower power mode in which the controller 120 disables software applications executing on the controller 120, in which the controller 120 disables content rendered on the display, and in which the controller 120 disables a power connection to the electronic communication port 114.

In one implementation, the modular computer system 100 includes the chassis 110 including: a latch 170 arranged proximal the slot and configured to de-couple a module, in the module kit, from the module slot 112 of the chassis 110 responsive application of an actuation force from a user; and a proximity sensor 172 coupled to the latch 170. In this implementation, the modular computer system 100 can: read electrical values from the proximity sensor 172; detect an open position of the latch 170 based on the electrical values from the proximity sensor 172; and, in response to detecting the open position, generate the prompt requesting the user to select a particular module in the module kit.

In another implementation, the modular computer system 100 includes the chassis 110 including an access panel 174: coupled to the latch 170; spanning across the input deck 117 of the chassis 110; arranged over the electronic communication port 114 coupled to the controller 120; and operable in an open configuration to enable the user to access the electronic communication port 114 from the input deck 117 of the chassis 110. In this implementation, the modular computer system 100 can further include a set of fasteners coupling the module to the electronic communication port 114 in order to transiently retain the module within the module slot 112.

In one example, the modular computer system 100 can: read a first electrical value from the proximity sensor 172; and detect the latch 170 in an open position based on the first electrical value. Additionally, in response to detecting the latch 170 in the open position, the computer system can: generate a prompt requesting a user to select a module, in the module kit, configured to install within the module slot 112 of the chassis 110; display the prompt at the display for the user; and, in response to receiving selection of the graphics processing module 135, in the module kit, initiate a graphics module swap mode to deactivate software applications executing on the controller 120, disable content rendered on the display, and disable a power connection to the electronic communication port 114.

In another example, the modular computer system 100 can: read a first electrical value from the proximity sensor 172; and detect the latch 170 in an open position based on the first electrical value. Additionally, in response to detecting the latch 170 in the open position, the modular computer system 100 can: generate a prompt requesting a user to select a module, in the module kit, configured to install within the module slot 112 of the chassis 110; display the prompt at the display for the user; in response to receiving selection of the memory module 150, in the module kit, initiate a memory module 150 swap mode to deactivate software applications executing on the controller 120 and transfer working data stored in the second memory unit 153 to the first memory unit 118; and, following transfer of the working data to the first memory unit 118, disable a power connection to the electronic communication port 114.

In another example, the modular computer system 100 can: access a graphics processing allocation value from the controller 120 for rending content on the display; and detect the graphics processing allocation value exceeding a graphics processing allocation threshold. Additionally, in response to the graphics processing value exceeding the graphics processing allocation threshold, the modular computer system 100 can: generate a prompt requesting a user to install the graphics processing module 135 within the module slot 112 of the chassis 110; display the prompt at the display for the user; and initiate a graphics module swap mode, during the graphics module swap mode, in which the controller 120 deactivates software applications executing on the controller 120, in which the controller 120 disables content rendered on the display, and in which the controller 120 disables a power connection to the electronic communication port 114.

In yet another example, the modular computer system 100 can: access a historical record of software applications previously executed on the controller 120; predict initialization of a software application corresponding to a graphics processing allocation exceeding a graphics processing allocation threshold; and generate the prompt requesting the user to install the graphics processing module 135 within the module slot 112 of the chassis no.

### 10. Registering and Distributing Module Kit

As described in U.S. Non-Provisional application Ser. No. 17/736,765, filed on 4 May 2022, the modular computer system 100 can maintain a data store that includes a library, data set, or database of each module in the module kit, to include: a description; identifying information (e.g., serial number, date of manufacture, place of manufacture, lot/batch number); assigned QR code; and a website or web address to which the QR code redirects a user's mobile device browser. In one variation of the implementation, the library can additionally include a module record corresponding to an individual module in the module kit and include a record of consumption activity of the module. The consumption activity data can be aggregated into an integrity status of the module by the system 100. In one alternative implementation, the data store can also include a module registration and tracking dataset, through which the system 100 can: verify and authenticate the provenance of the module and, through cross-reference of the serial number, date/site of manufacture, and date of first retail sale; and validate the authenticity and safety of the module to its first and subsequent purchasers.

In one implementation, the modular computer system can 100: access a historical record of software applications previously executed on the controller; link modules in the module record—representing modules owned and operated by the user—to software applications in the historical record; and in response to identifying absence of a link between a software application in the historical record to a module in the module kit, prompting a user to retrieve a module for the software application. In particular, the modular computer system can: retrieve a module library representing a set of modules available for purchase by the user and compatible with the modular computer system; link the software application to a set of modules in the module library; generate a prompt for a user to select a set of modules compatible with the software application; and present the prompt, such as at an interactive display at the modular computer system 100. Thus, in response to receiving selection of a module in the set of modules from the user, the modular computer system can then redirect the user's mobile device browser to a web page associated with the module.

In one example, the modular computer system can: identify absence of a link between a 3D rendering software application (i.e., a graphic intensive application) and a graphics processing module in the user's module kit; retrieve a module library containing a set of graphics processing modules available for purchase by the user and compatible with the 3D rendering software application; generate a prompt for a user to select a particular graphics processing module in the set of graphics processing modules; and present the prompt at an interactive display at the modular computer system for the user. Therefore, the modular computer system can present recommendations for modules to a user to enable to user to improve computational and/or ergonomic performance of the modular computer system 100.

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A modular computer system comprising:
a chassis:
defining a slot arranged along a first lateral side of the chassis; and
comprising an electronic communication port arranged within the chassis and extending into the slot;
a controller arranged within the chassis and electronically coupled to the electronic communication port;
a first set of heat pipes thermally coupled to the controller and extending proximal the slot of the chassis;
a display coupled to the chassis; and
a module kit:
comprising:
a cooling module defining a first mass and comprising:
a first frame defining a first external geometry and configured to transiently couple the first lateral side of the chassis to locate the cooling module within the slot; and
a first set of fans configured to thermally couple the first set of heat pipes to dissipate heat transferred from the controller; and
a graphics processing module defining a second mass, greater than the first mass, and comprising:
a second frame defining a second external geometry, greater than the second external geometry, and configured to transiently couple the first lateral side of the chassis to locate the graphics processing module within the slot;
a graphics processing unit configured to electronically couple the electronic communication port to transmit electrical signals from the graphics processing unit to the controller;
a second set of heat pipes extending within the second frame and thermally coupled to the graphics processing unit; and
a second set of fans configured to thermally couple the first set of heat pipes and the second set of heat pipes to dissipate heat transferred from the controller and the graphics processing unit; and
operable in a first configuration comprising the cooling module located within the slot and thermally coupling the controller to dissipate heat generated from the controller; and
operable in a second configuration comprising the graphics processing module located within the slot, electrically coupling the controller to transmit electrical signals from the graphics processing unit, and thermally coupling the controller to dissipate heat generated from the controller and the graphics processing unit.

2. The system of claim 1:
further comprising a first battery:
arranged within the chassis;
defining a first energy storage capacity; and
configured to electrically couple the controller to transmit electrical energy stored within the first battery to the controller;
wherein the module kit further comprises a power module comprising:
a third frame configured to transiently couple the first lateral side of the chassis to locate the power module within the slot;
a third set of fans configured to thermally couple the first set of heat pipes to dissipate heat transferred from the controller; and
a second battery defining a second energy storage capacity, greater than the first energy storage capacity, and configured to electrically couple the electronic communication port to transmit electrical energy stored within the second battery to the controller; and
wherein the module kit is operable in a third configuration comprising the power module extending within the slot, electrically coupling the controller to transmit electrical power stored within the second battery to the controller, and thermally coupling the controller to dissipate heat generated from the controller.

3. The system of claim 2:
wherein the power module further comprises a third set of heat pipes extending within the third frame and thermally coupled to the second battery; and
wherein the third set of fans is configured to thermally couple the first set of heat pipes to dissipate heat transferred from the controller and thermally couple the third set of heat pipes to dissipate heat transferred from the second battery.

4. The system of claim 2, wherein the controller is configured to:
during a first time period:
at a first time, read a first state of charge from the first battery arranged within the chassis;
in response to the first state of charge exceeding a threshold state of charge, direct electrical energy stored within the second battery to the controller;
at a second time following the first time, read a second state of charge from the second battery of the power module; and
in response to the second state of charge falling below a threshold state of charge, direct electrical energy stored within the first battery to the controller; and
during a second time period:
at a third time, read a third state of charge from the first battery arranged within the chassis; and
in response to the third state of charge falling below a threshold state of charge:
direct electrical energy stored within the second battery to the controller; and
direct electrical energy stored within the second battery to the first battery to increase electrical energy stored within the first battery.

5. The system of claim 1:
wherein the module kit further comprises an interface module comprising:
a third frame configured to transiently couple the first lateral side of the chassis to locate the interface module within the slot;
a third set of fans configured to thermally couple the first set of heat pipes to dissipate heat transferred from the controller; and
a set of connectors arranged along the third frame and configured to electronically couple the electronic communication port to transmit electrical signals from peripheral devices coupled to the set of connectors to the controller; and
wherein the module kit is operable in a third configured comprising the interface module extending within the slot, electrically coupling the controller to transmit electrical signals from the set of connectors to the controller, and thermally coupling the controller to dissipate heat generated from the controller.

6. The system of claim 1:
wherein the chassis:
defines a second slot:
arranged on a second lateral side, opposite the first lateral side, of the chassis; and
defining a rectangular geometry inset a bottom side of the chassis; and
comprises a second electronic communication port extending into the second slot and electronically coupled to the controller;
wherein the module kit further comprises an interface module comprising:
an enclosure configured to transiently couple the second lateral side of the chassis to locate the interface module within the second slot;
a first connector arranged on a first side of the enclosure and configured to interface with a peripheral device; and
a second connector arranged on a second side, opposite the first side, of the enclosure and configured to electronically couple the second electronic communication port to transmit electrical signals from the first connector to the controller; and
wherein the module kit is operable in a third configuration comprising:
the graphics processing module extending within the slot, electrically coupling the controller to transmit electrical signals from the graphics processing unit, and thermally coupling the controller to dissipate heat generated from the controller and the graphics processing unit; and
the interface module extending within the second slot and electrically coupling the controller to transmit electrical signals from the first connector to the controller.

7. The system of claim 1:
wherein the chassis further comprises:
a latch arranged proximal the slot and configured to de-couple a module, in the module kit, from the slot of the chassis responsive application of an actuation force from a user; and
a proximity sensor coupled to the latch; and
wherein the controller is configured to:
read a first electrical value from the proximity sensor;
detect the latch in an open position based on the first electrical value; and
in response to detecting the latch in the open position:
generate a prompt requesting a user to select a module, in the module kit, configured to install within the slot of the chassis;
display the prompt at the display for the user; and
in response to receiving selection of the graphics processing module, in the module kit, initiate a graphics module swap mode to deactivate software applications executing on the controller, disable content rendered on the display, and disable a power connection to the electronic communication port.

8. The system of claim 7:
wherein the chassis comprises an access panel:
coupled to the latch;
arranged over the electronic communication port; and
operable in an open configuration to enable a user to access the electronic communication port;
wherein the chassis comprises a first set of magnetic elements arranged along the first lateral side of the chassis proximal the slot;
wherein the first frame of the cooling module is formed of a ferrous material and configured to magnetically couple the first set of magnetic elements to transiently retain the cooling module within the slot; and
wherein the second frame of the graphics processing unit is formed of the ferrous material and configured to magnetically couple the first set of magnetic elements to transiently retain the graphics processing module within the slot.

9. The system of claim 7:
wherein the chassis comprises:
an input deck comprising an array of couplers, each coupler in the array of couplers comprising a magnetic element and an electric port coupled to the controller; and
an access panel coupled to the latch and arranged across the input deck over the electronic communication port; and
wherein the module kit further comprises:
a keyboard module comprising:
an array of keys; and
a first connector:
configured to magnetically couple the array of couplers to transiently retain the keyboard module across an upper region of the input deck; and
configured to electronically couple the array of couplers to transmit electrical signals from the array of keys to the controller; and
a trackpad module comprising:
a touch sensor; and
a second connector:
configured to magnetically couple the array of couplers to transiently retain the trackpad module across a lower region of the input deck; and
configured to electronically couple the array of couplers to transmit electrical signals from the touch sensor to the controller.

10. The system of claim 1:
wherein the chassis further comprises a first memory unit:
arranged within the chassis;
defining a first memory storage capacity; and
configured to electrically couple the controller to transmit data stored within the first memory unit to the controller;
wherein the module kit further comprises a memory module comprising:
a third frame configured to transiently couple the first lateral side of the chassis to locate the memory module within the slot;
a third set of fans configured to thermally couple the first set of heat pipes to dissipate heat transferred from the controller; and
a second memory unit defining a second memory storage capacity, greater than the first energy storage capacity, and configured to electrically couple the electronic communication port to transmit data stored within the second memory unit to the controller; and
wherein the module kit is operable in a third configuration comprising the memory module extending within the slot, electrically coupling the controller to transmit data stored within the second memory unit to the controller, and thermally coupling the controller to dissipate heat generated from the controller.

11. The system of claim 10:
wherein the chassis further comprises:
a latch arranged proximal the slot and configured to de-couple a module, in the module kit, from the slot of the chassis responsive to application of an actuation force from a user; and
a proximity sensor coupled to the latch; and
wherein the controller is configured to:
read a first electrical value from the proximity sensor;
detect the latch in an open position based on the first electrical value; and
in response to detecting the latch in the open position:
generate a prompt requesting a user to select a module, in the module kit, configured to install within the slot of the chassis;
display the prompt at the display for the user; and
in response to receiving selection of the memory module, in the module kit, initiate a memory module swap mode to deactivate software applications executing on the controller and transfer working data stored in the second memory unit to the first memory unit; and
following transfer of the working data to the first memory unit, disable a power connection to the electronic communication port.

12. The system of claim 1, wherein the controller is configured to:
access a graphics processing allocation value from the controller for rending content on the display; and
in response to the graphics processing value exceeding a graphics processing allocation threshold:
generate a prompt requesting a user to install the graphics processing module within the slot of the chassis;
display the prompt at the display for the user; and
initiate a graphics module swap mode, during the graphics module swap mode to:
deactivate software applications executing on the controller;
disable content rendered on the display; and
disable a power connection to the electronic communication port.

13. The system of claim 1:
wherein the chassis further comprises a first speaker unit:
arranged within the chassis;
defining a first frequency threshold; and
configured to electrically couple the controller to broadcast audio signals from the first speaker unit;
wherein the module kit further comprises an audio module comprising:
a third frame configured to transiently couple the first lateral side of the chassis to locate the audio module within the slot;
a third set of fans configured to thermally couple the first set of heat pipes to dissipate heat transferred from the controller; and
a second speaker unit, defining a second frequency threshold, less than the first frequency threshold, and configured to electrically couple the electronic communication port to broadcast audio signals from the second speaker unit; and
wherein the module kit is operable in a third configuration comprising the audio module extending within the slot, electrically coupling the controller to broadcast audio signals from the second speaker unit, and thermally coupling the controller to dissipate heat generated from the controller.

14. The system of claim 1:
wherein the first configuration comprises the cooling module extending within the slot to locate the first frame flush with the first lateral side of the chassis; and
wherein the second configuration comprises the graphics processing module extending within the slot to locate the second frame extending outwardly from the first lateral side of the chassis.

15. The system of claim 1:
wherein the chassis:
defines a second slot:
arranged on a second lateral side, opposite the first lateral side, of the chassis; and
defining a rectangular geometry inset a bottom side of the chassis; and
comprises:
a second electronic communication port extending into the second slot and electronically coupled to the controller;
an input deck comprising an array of couplers, each coupler in the array of couplers comprising a magnetic element and a port electrically coupled to the controller; and
an access panel arranged across the input deck over the electronic communication port and operable in an open configuration to enable a user to access the electronic communication port; and
wherein the module kit further comprises:
an interface module comprising:
an enclosure configured to transiently couple the second lateral side of the chassis to locate the interface module within the second slot;
a first connector arranged on a first side of the enclosure and configured to interface with a peripheral device; and
a second connector arranged on a second side, opposite the first side, of the enclosure and configured to electronically couple the second electronic communication port to transmit electrical signals from the first connector to the controller;
a keyboard module comprising:
an array of keys; and
a third connector:
configured to magnetically couple the array of couplers to transiently retain the keyboard module across an upper region of the input deck; and
configured to electronically couple the array of couplers to transmit electrical signals from the array of keys to the controller; and
a trackpad module comprising:
a touch sensor; and
a second connector:
configured to magnetically couple the array of couplers to transiently retain the trackpad module across a lower region of the input deck; and
configured to electronically couple the array of couplers to transmit electrical signals from the touch sensor to the controller.

16. A system comprising:
a chassis:
defining a slot arranged along a lateral side of the chassis; and
comprising an electronic communication port arranged within the chassis and extending into the slot;
a controller arranged within the chassis and electronically coupled to the electronic communication port;
a first heat pipe thermally coupled to the controller and extending proximal the slot of the chassis;
a module kit comprising:
a cooling module defining a first mass and comprising:
a first frame configured to transiently couple the lateral side of the chassis to locate the cooling module within the slot; and
a first fan configured to thermally couple the first heat pipe to dissipate heat transferred from the controller; and
a power module defining a second mass, greater than the first mass, and comprising:
a second frame configured to transiently couple the lateral side of the chassis to locate the power module within the slot;
a battery configured to electrically couple the electronic communication port to transfer electrical energy stored within the battery to the controller;
a second heat pipe extending within the second frame and thermally coupled to the second battery; and
a second fan configured to thermally couple the first heat pipe and the second heat pipe to dissipate heat transferred from the controller and the second battery.

17. The system of claim 16, wherein the module kit further comprises a graphics processing module:
defining a third mass greater than the first mass; and
comprising:
a third frame configured to transiently couple the lateral side of the chassis to locate the graphics processing module within the slot;
a graphics processing unit configured to electronically couple the electronic communication port to transmit electrical signals from the graphics processing unit to the controller;
a third heat pipe extending within the third frame and thermally coupled to the graphics processing unit; and
a third fan configured to thermally couple the first heat pipe and the third heat pipe to dissipate heat transferred from the controller and the graphics processing unit.

18. The system of claim 16, wherein the module kit further comprises an interface module:
defining a third mass greater than the first mass; and
comprising:
a third frame configured to transiently couple the lateral side of the chassis to locate the interface module within the slot;
a set of connectors arranged along the third frame and configured to electronically couple the electronic communication port to transmit electrical signals from peripheral devices coupled at the set of connectors to the controller;
a third heat pipe extending within the third frame and thermally coupled to the set of connectors; and
a third fan configured to thermally couple the first heat pipe and the third heat pipe to dissipate heat transferred from the controller and the set of connectors.

19. The system of claim 16, wherein the module kit further comprises a memory module:
defining a third mass greater than the first mass; and
comprising:
a third frame configured to transiently couple the first lateral side of the chassis to locate the memory module within the slot;
a memory unit configured to electrically couple the electronic communication port to transmit data stored within the memory unit to the controller;
a third heat pipe extending within the third frame and thermally coupled to the memory unit; and
a third fan configured to thermally couple the first heat pipe and the third heat pipe to dissipate heat transferred from the controller and the memory unit.

20. A modular computer system comprising:
a chassis:
defining a slot arranged along a lateral side of the chassis; and
comprising an electronic communication port arranged within the chassis and extending into the slot;
a controller arranged within the chassis and electronically coupled to the electronic communication port;
a first heat pipe thermally coupled to the controller and extending proximal the slot of the chassis;
a module kit comprising:
a power module comprising:
a first frame defining a first external geometry and configured to transiently couple the lateral side of the chassis to locate the power module within the slot;
a first fan configured to thermally couple the first heat pipe to dissipate heat transferred from the controller; and
a battery configured to electrically couple the electronic communication port to transfer electrical energy stored within the battery to the controller; and
a graphics processing module comprising:
a second frame defining a second external geometry and configured to transiently couple the lateral side of the chassis to locate the graphics processing module within the slot;
a graphics processing unit configured to electronically couple the electronic communication port to transmit electrical signals from the graphics processing unit to the controller;
a second heat pipe extending within the second frame and thermally coupled to the graphics processing unit; and
a second fan configured to thermally couple the first heat pipe and the second heat pipe to dissipate heat transferred from the controller and the graphics processing unit.
